(19) United States
(12) Patent Application Publication
(10) Pub. No.: US 2026/0281590 A1
(43) Pub. Date: Sep. 17, 2026

(54) COMPARATOR AND SOLID-STATE IMAGING DEVICE WITH MULTI-GAIN AD CONVERSION

(71) Applicant: Samsung Electronics Co., Ltd., Suwon-si (KR)

(72) Inventors: Haruhisa Naganokawa, Yokohama-shi (JP); Noriyuki Saruhashi, Yokohama-shi (JP); Hiroyuki Iwaki, Yokohama-shi (JP)

(21) Appl. No.: 19/563,381

(22) Filed: Mar. 11, 2026

(30) Foreign Application Priority Data
Mar. 12, 2025 (JP) JP-P-2025-038887

(51) Int. Cl. H04N 25/78; H03M 1/56; H04N 25/51; H04N 25/57

(52) U.S. Cl. CPC H04N 25/78; H03M 1/56; H04N 25/51; H04N 25/57

(57) ABSTRACT

A comparator includes a ramp signal input circuit configured to input a ramp signal, a plurality of pixel signal input circuits, each configured to input a pixel signal, and a comparator circuit configured to compare the ramp signal input from the ramp signal input circuit with the pixel signal input from one of the plurality of pixel signal input circuits and output a comparison result.

### CROSS-REFERENCE TO RELATED APPLICATION(S)

This application claims priority to and the benefit of Japanese Patent Application No. JP-P-2025-038887 filed with the Japan Property Office on Mar. 12, 2025, the disclosure of which is incorporated herein by reference.

### BACKGROUND

Recently, the miniaturization and high-performance of devices equipped with a camera, such as a mobile phone or a digital camera, have been rapidly advancing. Area reduction, speed increase, and low power consumption of a solid-state imaging device (an image sensor) may be important for the miniaturization and high-performance of such devices.

In a solid-state imaging device, a wide dynamic range, which represents the range of brightness that can be reproduced as an image, may be also one of the important factors. A method for achieving a wide dynamic range in the related art may involve combining a plurality of frames captured with different exposure levels, where an image obtained by one exposure corresponds to one frame. However, this method may cause motion blur (subject blurring) due to differences in exposure timing for the same pixel across the plurality of frames. In addition, this method may have difficulty in performing real-time signal processing for each frame when generating motion pictures or preview images by combining the plurality of frames.

In a single frame, development of technologies is also underway to achieve a wide dynamic range using pixel signals with two different charge-to-voltage conversion gains (hereinafter simply referred to as “conversion gains”)

### SUMMARY

Aspects of the present disclosure relate to a comparator and a solid-state imaging device.

To obtain a wider dynamic range, it may be important to increase a ratio of conversion gains in a pixel configuration having two or more conversion gains. However, in related art, an analog-to-digital (AD) converter is provided for each conversion gain, which may result in a decrease in frame rate, or an increase in power consumption and circuit area. In addition, in related art, an area of input capacitance and a differential unit, which occupy a large portion of a comparator unit, may increase, which may affect manufacturing costs. Accordingly, when a plurality of conversion gains are provided, the number of comparator units also increases in proportion to the number of conversion gains. As a result, the circuit area of the solid-state imaging device may increase.

Therefore, implementations of the present disclosure provide a comparator and a solid-state imaging device configured to achieve a wide dynamic range within a single frame while suppressing an increase in circuit area of a comparator.

The above and other features may be achieved by the following.
(1) A comparator configured to a ramp signal and an analog pixel signal in an AD conversion unit configured to convert the pixel signal into a digital signal includes a single ramp signal input unit configured to receive the ramp signal, a plurality of pixel signal input units, each configured to receive the pixel signal, and a comparison unit configured to compare the ramp signal, received from the ramp signal input unit, with a pixel signal, received from one of the plurality of pixel signal input units, and to output a comparison result.
In the comparator set forth in (1), (2) the comparator may further include a selection unit configured to select one of the plurality of pixel signal input units.
(3) A solid-state imaging device includes a pixel configuration configured to switch a conversion gain corresponding to a rate at which a charge generated in a pixel is converted into a voltage, and the comparator of claim 2, configured to input a pixel signal from the pixel configuration to the pixel signal input unit corresponding to the conversion gain
In the solid-state imaging device set forth in one of (1) to (3), (4) the comparison unit may be configured to sequentially compare the ramp signal with the pixel signal for each conversion gain.
In the solid-state imaging device set forth in one of (1) to (4), (5) the comparison unit may be configured to, for each conversion gain, compare a pixel signal from the reset pixel configuration with the ramp signal and then compare a pixel signal corresponding to a captured image with the ramp signal.
In the solid-state imaging device set forth in (5), (6) the ramp signal input unit and the pixel signal input unit selected by the selection unit may form a differential pair unit, the differential pair unit may include a first transistor configured to receive the ramp signal, a first switch configured to initialize the first transistor, a second transistor configured to receive the pixel signal, and a second switch configured to initialize the second transistor, the first switch may be turned on once immediately after the pixel configuration is reset to initialize the first transistor, and the second switch corresponding to the conversion gain may be turned on for each conversion gain to initialize the second transistor.
In the solid-state imaging device set forth in one of (1) to (6), the pixel configuration may include a plurality of pixels having different sensitivities.
In the solid-state imaging device set forth in one of (1) to (7), (8) the comparison unit may be configured to sequentially compare pixel signals from the plurality of pixels with the ramp signal for each pixel.
In the solid-state imaging device set forth in one of (7) or (8), (9) the comparison unit may be configured to, for each conversion gain, compare a pixel signal from the reset pixel configuration with the ramp signal and then compare a pixel signal corresponding to a captured image with the ramp signal.
In the solid-state imaging device set forth in (9), (10) the ramp signal input unit and the pixel signal input unit selected by the selection unit may form a differential pair unit, the differential pair unit may include a first transistor configured to receive the ramp signal, a first switch configured to initialize the first transistor, a second transistor configured to receive the pixel signal, and a second switch configured to initialize the second transistor, the first switch may be turned on once immediately after the pixel configuration is reset to initialize the first transistor, and the second switch corresponding to the conversion gain may be turned on for each conversion gain to initialize the second transistor.
In the solid-state imaging device set forth in one of (1) to (6), (11) the pixel configuration and the plurality of pixel signal input units may be connected by a single line.
In the solid-state imaging device set forth in (6), (12) the first switch may be configured to connect a gate terminal and a source or drain terminal of the first transistor, the second switch may be configured to connect a gate terminal and a source or drain terminal of the second transistor, the first switch may be turned on once immediately after the pixel configuration is reset to connect the gate terminal and the source or drain terminal of the first transistor to initialize the first transistor, and the second switch corresponding to the conversion gain may be turned on for each conversion gain to connect the gate terminal and the source or drain terminal of the second transistor to initialize the second transistor.
In the solid-state imaging device set forth in (10), (13) the first switch may be configured to connect a gate terminal and a source or drain terminal of the first transistor, the second switch may be configured to connect a gate terminal and a source or drain terminal of the second transistor, the first switch may be turned on once immediately after the pixel configuration is reset to connect the gate terminal and the source or drain terminal of the first transistor to initialize the first transistor, and the second switch corresponding to the conversion gain may be turned on for each conversion gain to connect the gate terminal and the source or drain terminal of the second transistor to initialize the second transistor.
In the solid-state imaging device set forth in (5), (14) the comparison unit may include a differential pair unit configured to differentially amplify the ramp signal and the pixel signal, the differential pair unit may include a first switch configured to initialize a first transistor configured to receive the ramp signal and a second switch configured to initialize a second transistor configured to receive the pixel signal, the first switch may be turned on once immediately after the pixel configuration is reset to initialize the first transistor, and the second switch corresponding to the conversion gain may be turned on for each conversion gain to initialize the second transistor.
In the solid-state imaging device set forth in (9), (15) the comparison unit may include a differential pair unit configured to differentially amplify the ramp signal and the pixel signal, the differential pair unit may include a first switch configured to initialize a first transistor configured to receive the ramp signal and a second switch configured to initialize a second transistor configured to receive the pixel signal, the first switch may be turned on once immediately after the pixel configuration is reset to initialize the first transistor, and the second switch corresponding to the conversion gain may be turned on for each conversion gain to initialize the second transistor.

### BRIEF DESCRIPTION OF DRAWINGS

FIG. 1 is a schematic diagram illustrating a configuration of a solid-state imaging device according to a first implementation.

FIG. 2 is a circuit diagram illustrating a pixel circuit illustrated in FIG. 1.

FIG. 3 is a circuit diagram illustrating a configuration of a comparator illustrated in FIG. 1.

FIG. 4 is a flow chart illustrating an overview of a processing sequence in the solid-state imaging device illustrated in FIG. 1.

FIG. 5 is a timing chart illustrating an overview of an operation of the solid-state imaging device illustrated in FIG. 1.

FIG. 6 is a circuit diagram illustrating a pixel circuit of a solid-state imaging device according to a second implementation.

FIG. 7 is a circuit diagram illustrating a configuration of a comparator of the solid-state imaging device according to the second implementation.

FIG. 8 is a timing chart illustrating an overview of an operation of the solid-state imaging device according to the second implementation.

FIG. 9 is a graph illustrating a signal-to-noise ratio (SNR) curve with respect to illuminance of the solid-state imaging device according to the second implementation.

FIG. 10 is a circuit diagram illustrating a pixel circuit of a solid-state imaging device according to a third implementation.

FIG. 11 is a timing chart illustrating an overview of an operation of the solid-state imaging device according to the third implementation.

FIG. 12 is a circuit diagram illustrating a pixel circuit of a solid-state imaging device according to a fourth implementation.

FIG. 13 is a timing chart illustrating an overview of an operation of the solid-state imaging device according to the fourth implementation.

### DETAILED DESCRIPTION

Hereinafter, implementations of the present disclosure will be described more fully with reference to the accompanying drawings. In the following drawings, the same reference numerals denote the same components, and a size of each component in the drawings is represented at a different ratio from the implementations for clarity and ease of description.

It will be understood that when an element or layer is referred to as being “on” or “above” another element or layer, the element or layer may be directly on another element or layer or intervening elements or layers.

As used herein, the singular forms “a,” “an” and “the” are intended to include the plural forms as well, unless the context clearly indicates otherwise. It will be further understood that the terms “comprises” and/or “comprising” used herein specify the presence of stated features or components, but do not preclude the presence or addition of one or more other features or components.

In addition, the use of the term “the” and similar referential terms applies to both singular and plural.

The steps of all methods described herein can be performed in any suitable order unless otherwise indicated herein or otherwise clearly contradicted by context. Inventive concepts are not limited to the described order of the steps. The use of any and all examples, or exemplary language (for example, “such as”) provided herein, is intended merely to better illuminate the present disclosure and does not pose a limitation on the scope of the present disclosure unless otherwise claimed.

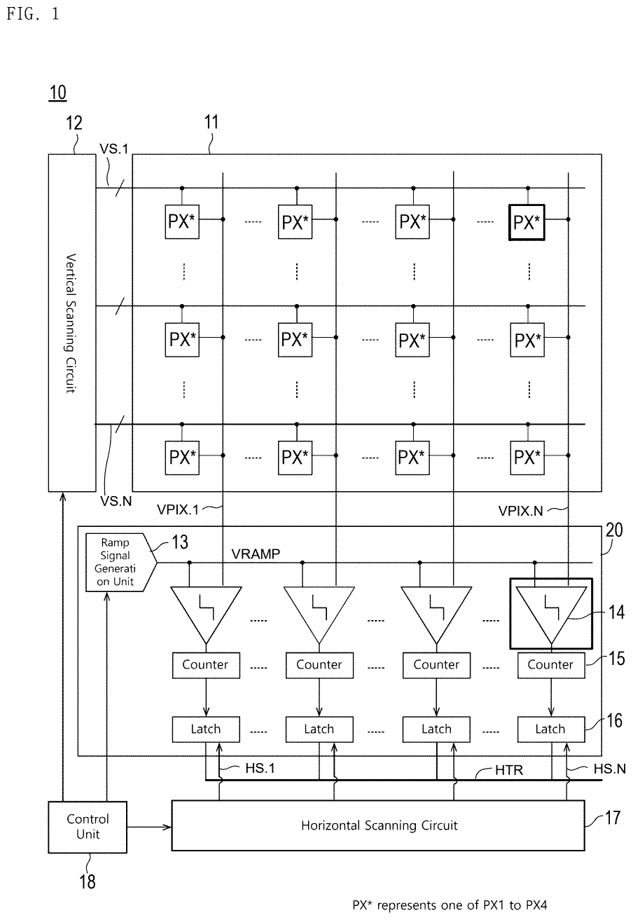

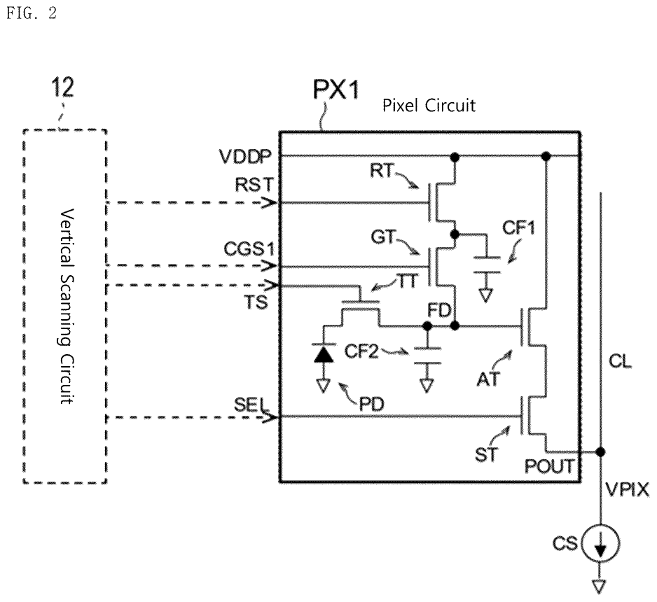

FIG. 1 is a schematic diagram illustrating a configuration of a solid-state imaging device 10 according to a first implementation, and FIG. 2 is a circuit diagram illustrating a pixel circuit (pixel configuration) illustrated in FIG. 1.

As illustrated in FIG. 1, the solid-state imaging device 10 may include a pixel array unit 11, a vertical scanning circuit 12, a ramp signal generation unit 13, a plurality of comparators 14, a plurality of counters 15, a plurality of latches 16, a horizontal scanning circuit 17, and a control unit 18. The ramp signal generation unit 13, the plurality of comparators 14, the plurality of counters 15, and the plurality of latches 16 may form an analog-to-digital conversion unit (AD conversion unit) 20.

The pixel array unit 11 may include a plurality of pixel circuits PX* arranged two-dimensionally (arranged in a matrix) in a row direction and a column direction. As illustrated in FIG. 2, in the present implementation, a pixel circuit PX1 is described as an example of the pixel circuit PX*. Other examples of the pixel circuit PX* will be described in second to fourth implementations.

The pixel circuit PX1 may include a photoelectric conversion element (pixel) PD, a transfer transistor TT, a reset transistor RT, a gain select transistor GT, an amplification transistor AT, and a select transistor ST. The pixel circuit PX1 may perform photoelectric conversion of incident light and outputs a pixel signal VPIX based on the amount of incident light. The photoelectric conversion element PD may be, for example, a photodiode or a phototransistor.

A gate terminal, a drain terminal, and a source terminal of the reset transistor RT may be connected to an RST input terminal, a pixel power supply VDDP, and a drain terminal of the gain select transistor GT, respectively. A capacitance CF1 of a floating diffusion FD may be formed between a connection portion of the source terminal of the reset transistor RT and the drain terminal of the gain select transistor GT and a ground.

A gate terminal, a drain terminal, and a source terminal of the gain select transistor GT may be connected to a CGS1 input terminal, the source terminal of the reset transistor RT, and the source terminal of the transfer transistor TT, respectively.

A gate terminal, a drain terminal, and a source terminal of the transfer transistor TT may be connected to a TS input terminal, a cathode terminal of a photoelectric conversion element PD, and the source terminal of the gain select transistor GT, respectively. A capacitance CF2 of the floating diffusion FD may be formed between a connection portion of the source terminal of the transfer transistor TT and the source terminal of the gain select transistor GT and the ground.

A gate terminal, a drain terminal, and a source terminal of an amplification transistor AT may be connected to the source terminal of the transfer transistor TT, the pixel power supply VDDP, and the drain terminal of the select transistor ST, respectively.

The gate terminal, the drain terminal, and the source terminal of the select transistor ST may be connected to an SEL input terminal, the source terminal of the amplification transistor AT, and an output terminal POUT of the pixel circuit PX1, respectively. A signal having a voltage level based on the amount of charge accumulated in the floating diffusion FD may be output from the output terminal POUT.

As illustrated in FIG. 1, the pixel array unit 11 may output analog pixel signals VPIX.1 to VPIX.N for the pixel circuits PX1 in a row selected by the vertical scanning circuit 12. The pixel signals VPIX.1 to VPIX.N are the pixel signals of the pixel circuits PX1 in a first column to an N-th column of the selected row. In the following description, a plurality of pixel circuits PX1 arranged in the row direction are referred to as a pixel row, and a plurality of pixel circuits PX1 arranged in the column direction are referred to as a pixel column.

The pixel circuit PX1 according to the present implementation may operate at one of two conversion gains: a high conversion gain and a low conversion gain. The conversion gain may correspond to a ratio at which charges (electrons) generated in the photoelectric conversion element PD is converted into a voltage. The charges generated in the photoelectric conversion element PD may be transferred to the floating diffusion FD and accumulated, and the charges accumulated in the floating diffusion FD may be converted into a voltage.

For example, in FIG. 2, the floating diffusion FD may be configured by the capacitance CF2 when the pixel circuit PX1 is at a high conversion gain, and may be configured by the capacitances CF1 and CF2 when the pixel circuit PX1 is at a low conversion gain.

For example, the capacitance of the floating diffusion FD in the pixel circuit PX1 is larger when the pixel circuit PX1 is at a low conversion gain than when the pixel circuit PX1 is at a high conversion gain. Therefore, when the same amount of charge is accumulated in the floating diffusion FD, a potential caused by the charges accumulated in the floating diffusion FD in the pixel circuit PX1 is lower when the pixel circuit PX1 is at a low conversion gain than when the pixel circuit PX1 is at a high conversion gain.

In addition, the conversion gain of the pixel circuit PX1 may also vary depending on the capacitances CF1 and CF2 of the floating diffusion FD. When the capacitances CF1 and CF2 increase, the conversion gain of the pixel circuit PX1 may decrease. When the capacitances CF1 and CF2 decreases, the conversion gain may increase.

The solid-state imaging device 10 may select whether to operate each pixel circuit PX1 in a high conversion gain mode in which each pixel operates at a high conversion gain, or a low conversion gain mode in which each pixel operates at a low conversion gain. In the example illustrated in FIG. 2, the conversion gain mode may be selected by a CGS1 control signal. In the following description, the high conversion gain mode is also referred to as a “high conversion gain (HCG) mode,” and the low conversion gain mode is also referred to as a “low conversion gain (LCG) mode.”

When the plurality of pixel circuits PX1 in the pixel array unit 11 operate in the HCG mode, a dark area may be clearly expressed in a generated image. When the plurality of pixel circuits PX1 in the pixel array unit 11 operate in the LCG mode, a bright area may be clearly expressed in the generated image.

In the present implementation, each pixel circuit PX1 in the row selected by the vertical scanning circuit 12 may continuously operate in the HCG mode and the LCG mode in a single readout period. An image having a wide dynamic range may be generated by merging the image where the dark area is clearly expressed by the high conversion gain and the image where the bright area is clearly expressed by the low conversion gain in a single frame.

The vertical scanning circuit 12 may output a pulse signal to a signal line VS.1 to VS.n corresponding to a selected row to select a single row among the plurality of pixel rows in the pixel array unit 11. The vertical scanning circuit 12 may include a vertical decoder and a vertical driving circuit. The vertical decoder may decode position information of the pixel circuit PX1, specified by the control unit 18, to specify a readout row in the vertical direction, for example, to select a single row among the plurality of pixel rows. The vertical driving circuit may provide a pulse signal to the pixel circuit PX1 of the readout row, defined by the vertical decoder, to drive the pixel circuit PX1.

The ramp signal generation unit 13 may be a DA conversion circuit providing a ramp signal VRAMP to the AD conversion unit 20. The ramp signal generation unit 13 may generate a ramp-wave voltage signal (hereinafter referred to as a “ramp signal”) VRAMP having a voltage level monotonically decreasing as time passes, and may convert the analog signal from the pixel circuit PX1 into a digital signal.

The comparator 14 may compare the ramp signal VRAMP, generated by the ramp signal generation unit 13, with the pixel signal VPIX from the pixel array unit 11 and may output a comparison result. VPIX represents a certain pixel signal among VPIX.1 to VPIX.N. The comparison result, for example, may be a logic high level when the ramp signal VRAMP is greater than or equal to the pixel signal VPIX, and may be a logic low level when the ramp signal VRAMP is less than the pixel signal VPIX. For example, the comparator 14 may be configured to output a logic high level from the start of measurement of the pixel signal VPIX until the pixel signal VPIX and the ramp signal VRAMP intersect each other, and output a logic low level after the pixel signal VPIX and the ramp signal VRAMP intersect each other. The configuration and function of the comparator 14 will be described in detail later.

The counter 15 may receive an output signal of the comparator 14 as an enable signal and count an enable period using a clock input of a predetermined period. The counter 15 may count the number of clocks input from the start of measurement until the pixel signal VPIX and the ramp signal VRAMP intersect each other. The count result (count value) of the counter 15 may be a digital value obtained by digitizing the analog pixel signal VPIX.

The counter 15 may be, for example, an up-counter or a down-counter. When the counter 15 is an up-counter, the counter 15 may count up from an initial value 0 during a period in which the enable signal is active (logic high level). When the counter 15 is a down-counter, the counter 15 may count down from an initial value M during a period in which the enable signal is active.

The latch 16 may hold (latch) a count value of the counter 15 and perform correlated double sampling (CDS) processing. The latch 16 may include a plurality of (for example, two) latch circuits and a subtraction circuit. The ADC 20 may perform AD conversion twice for an RST phase corresponding to a reset level pixel signal VPIX and a SIG phase corresponding to a signal level pixel signal VPIX. A reset level may correspond to an output level (DARK level) from the pixel circuit PX1 immediately after it is reset. The output signal from the pixel circuit PX1 immediately after being reset may include noise such as fixed pattern noise or reset noise. A signal level may correspond to the output level of the image captured of the subject. The signal level may include the above-mentioned noise. The latch circuit may hold the count value of the counter 15 in the RST phase and the SIG phase. The count value held in the latch 16 is referred to as an “AD conversion value.”

The latch 16 may perform CDS processing by calculating a difference between a count value corresponding to the signal level pixel signal VPIX and a count value corresponding to the reset level pixel signal VPIX. The CDS processing may remove a variation in the pixel signal VPIX for each pixel circuit PX1. For example, noise such as fixed pattern noise or reset noise of the pixel value including the variation for each pixel circuit PX1 may be removed by subtracting the count value of the counter 15 in the RST phase from the count value of the counter 15 in the SIG phase. Thus, the pixel value corresponding to the signal level after noise removal may be extracted. The latch 16 may output the difference to a horizontal transfer line HTR in synchronization with driving signals HS.1 to HS.N provided from the horizontal scanning circuit 17.

In addition, the subtraction of the count value of the RST phase from the count value of the SIG phase may be performed using an up/down-counter. The counter 15 may include an up/down-counter, and the latch 16 may be omitted. The counter 15 may count down in the RST phase and count up in the SIG phase. Thus, the subtraction of the count value of the RST phase from the count value of the SIG phase may be equivalently performed within the counter 15, and a count value based on the subtraction result may be held in the counter 15. For example, noise such as fixed pattern noise or reset noise of the pixel value including the variation for each pixel circuit PX1 may be removed by the two count processes of counting down in the RST phase and counting up in the SIG phase. As a result, the pixel value corresponding to the signal level after noise removal may be extracted.

The horizontal scanning circuit 17 may output a pulse signal to a select signal line HS corresponding to a selected column to select a single column from among the plurality of pixel columns in the pixel array unit 11. HS represents a certain select signal line among HS.1 to HS.N. The horizontal scanning circuit 17 may include a horizontal decoder and a horizontal driving circuit. The horizontal decoder may decode location information of the pixel circuit PX1, specified by the control unit 18, to specify a readout column in the horizontal direction, for example, to select a single column from among the plurality of pixel columns. The horizontal driving circuit may provide a pulse signal to the latch 16 of the readout column, specified by the horizontal decoder, to read out the data held in the latch 16.

The control unit 18 may generate various timing signals, control signals, or the like, and may perform driving control of the vertical scanning circuit 12, the ramp signal generation unit 13, the horizontal scanning circuit 17, the AD conversion unit 20, or the like, based on the generated signals. The timing signals may include, for example, a reset signal, and the control signals may include, for example, a CGS1 signal, a TS signal, an SEL signal, a PC1 signal, a PC2 signal, an R1 signal, a P1 signal, a P2 signal, or the like.

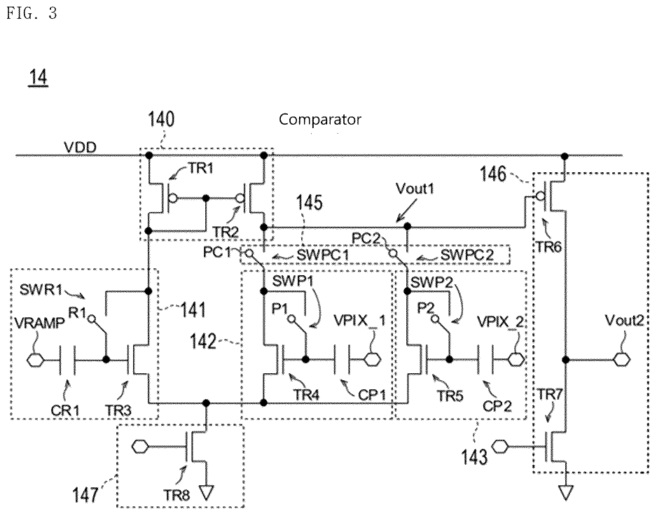

FIG. 3 is a circuit diagram illustrating a configuration of the comparator 14 illustrated in FIG. 1. The comparator 14 may include a current mirror circuit 140, a ramp signal input unit 141, a first pixel signal input unit 142, a second pixel signal input unit 143, a selection unit 145, an output circuit 146, and a bias circuit 147.

The ramp signal input unit 141 may include a ramp input terminal, an input capacitor CR1, a ramp signal initialization switch SWR1, and a transistor TR3. The input capacitor CR1 may have one terminal of the input capacitor connected to the ramp input terminal, and another terminal connected to a gate terminal of the transistor TR3. The input capacitor CR1 may prevent a DC component, included in the ramp signal VRAMP input from the ramp input terminal, from being transmitted to the transistor TR3.

The first pixel signal input unit 142 may include a VPIX_1 input terminal, an input capacitor CP1, a pixel signal initialization switch SWP1, and a transistor TR4. The input capacitor CP1 may have one terminal connected to the VPIX_1 input terminal, and another terminal connected to a gate terminal of the transistor TR4. The input capacitor CP1 may prevent a DC component, included in the pixel signal VPIX input from the VPIX_1 input terminal, from being transmitted to the transistor TR4.

The second pixel signal input unit 143 may include a VPIX_2 input terminal, an input capacitor CP2, a pixel signal initialization switch SWP2, and a transistor TR5. The input capacitor CP2 may have one terminal connected to the VPIX_2 input terminal, and another terminal connected to a gate terminal of the transistor TR5. The input capacitor CP2 may prevent a DC component, included in the pixel signal VPIX input from the VPIX_2 input terminal, from being transmitted to the transistor TR5.

In the present implementation, the VPIX_1 input terminal of the first pixel signal input unit 142 and the VPIX_2 input terminal of the second pixel signal input unit 143 may be connected to each pixel circuit PX1 of the pixel column by a single line CL (see FIGS. 2 and 3).

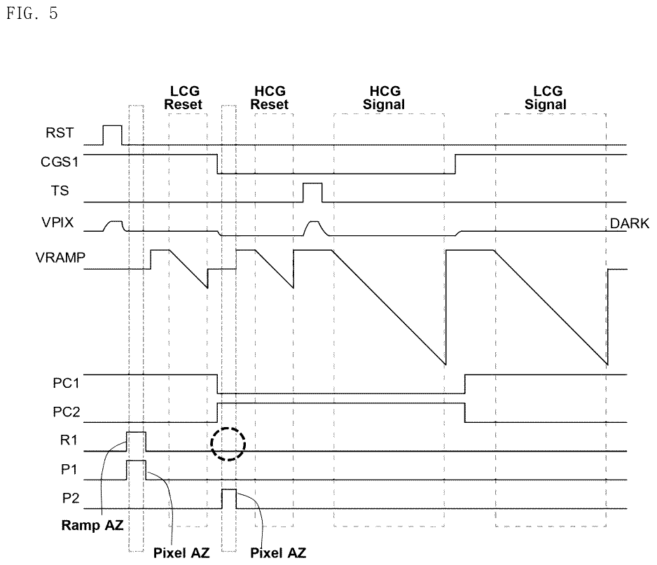

The selection unit 145 may select one of the first pixel signal input unit 142 and the second pixel signal input unit 143 by turning on one of the current path control switches SWPC1 and SWPC2 based on current path control signals PC1 and PC2. The current path control signals PC1 and PC2 may be controlled by the control unit 18 to be mutually exclusively active (refer to FIG. 5).

The ramp signal input unit 141 and the pixel signal input unit selected by the selection unit 145, among the first pixel signal input unit 142 and the second pixel signal input unit 143, may form a differential pair unit.

When SWPC1 is turned ON, the transistors TR3 (the first transistor) and TR4 (the second transistor) may form a differential pair. The current mirror circuit 140 and the differential pair may function as a comparator unit. When SWPC2 is turned ON, the transistors TR3 (the first transistor) and TR5 (the second transistor) may form a differential pair. The current mirror circuit 140 and the differential pair may function as a comparator unit.

In some implementations, a current flowing through the transistor TR3, which varies according to the ramp signal applied to its gate, may serve as a ramp-side signal supplied to one side of the differential pair. The ramp-side signal may be provided to one side of the differential pair as an output of the ramp signal input unit 141. Similarly, a current flowing through the transistor TR4/TR5, which varies according to the pixel signal applied to its gate, may serve as a pixel-side signal supplied to the other side of the differential pair. The pixel-side signal may be provided to the other side of the differential pair as an output of the selected one of the pixel signal input units 142, 143.

The gate terminals of the transistors TR1 and TR2 of the current mirror circuit 140 may be connected to each other, and the drain terminals of the transistors TR1 and TR2 may be connected to a power supply line VDD. The source terminal of the transistor TR1 may be connected to the gate terminal of the transistor TR1, the gate terminal of the transistor TR2, and the drain terminal of the transistor TR3. The source terminal of the transistor TR2 may be connected to one terminal of the current path control switches SWPC1 and SWPC2 of the selection unit 145 and the gate terminal of a transistor TR6.

The drain terminal of the transistor TR3 may be connected to one output terminal of the current mirror circuit 140, and the source terminal of the transistor TR3 may be connected to one drain terminal of a transistor TR8 in the bias circuit 147.

The ramp signal initialization switch SWR1 (a first switch) may be turned ON in response to a ramp auto-zero signal RampAZ. When the ramp signal initialization switch SWR1 is turned ON, the gate terminal and the drain terminal of the transistor TR3 may be connected to each other, and thus the transistor TR3 may be initialized. As a result, the offset of the ramp signal input unit 141 may be removed.

The drain terminal of the transistor TR4 may be connected to another terminal of the current path control switch SWPC1 of the selection unit 145, and the source terminal of the transistor TR4 may be connected to the drain terminal of the transistor TR8 in the bias circuit 147.

The pixel signal initialization switch SWP1 (a second switch) may be turned on in response to a pixel auto-zero signal PixelAZ. When the ramp signal initialization switch SWR1 is turned on, the gate terminal and the drain terminal of the transistor TR4 may be connected to each other, and thus the transistor TR4 may be initialized. As a result, the offset of the first pixel signal input unit 142 may be removed.

The drain terminal of the transistor TR5 is connected to the other terminal of the current path control switch SWPC2 of the selection unit 145, and the source terminal of the transistor TR5 is connected to the drain terminal of the transistor TR8 in the bias circuit 147.

The pixel signal initialization switch SWP2 (a second switch) may be turned on in response to the pixel auto-zero signal PixelAZ. When the pixel signal initialization switch SWP2 is turned on, the gate terminal and the drain terminal of the transistor TR5 may be connected to each other, and thus the transistor TR5 may be initialized. As a result, the offset of the second pixel signal input unit 143 may be removed.

The comparator unit may compare the ramp signal VRAMP, input from the ramp signal input unit 141, with the pixel signal VPIX, input from the pixel signal input unit selected by the selection unit 145, among the first pixel signal input unit 142 and the second pixel signal input unit 143, and may output a comparison result. In the example illustrated in FIG. 3, the comparator unit may output a logic high level when the ramp signal VRAMP is greater than or equal to the pixel signal VPIX. The comparator unit may output a logic low level when the ramp signal VRAMP is less than the pixel signal VPIX.

The output circuit 146 may include transistors TR6 and TR7 and an output terminal Vout2. A gate terminal of the transistor TR6 may be connected to the source terminal of the transistor TR2, and a drain terminal of the transistor TR6 may be connected to the power supply line VDD. In addition, a source terminal of the transistor TR6 may be connected to a drain terminal of the transistor TR7 and the output terminal Vout2. The output circuit 146 may control an output current based on a control signal input to the gate terminal of the transistor TR7, and may output a comparison result, obtained by the comparator unit, from the output terminal Vout2.

The bias circuit 147 may include a transistor TR8 and control a predetermined bias current to flow to the comparator unit based on a control signal input to a gate terminal of the transistor TR8.

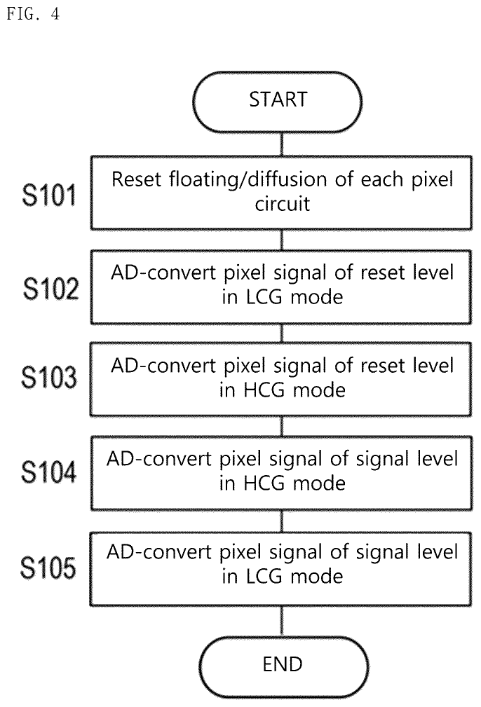

FIG. 4 is a flow chart illustrating an overview of a processing sequence in the solid-state imaging device illustrated in FIG. 1, and FIG. 5 is a timing chart illustrating an overview of an operation of the solid-state imaging device illustrated in FIG. 1.

As illustrated in FIG. 4, in operation S101, the control unit 18 may reset the floating diffusion FD of each pixel circuit PX1. For example, the control unit 18 may control the reset transistor RT and the gain select transistor GT to be turned on. As illustrated in FIG. 5, the RST signal may be input to the RST input terminal of the reset transistor RT for a predetermined period. Accordingly, the pixel power supply VDDP may be applied to the floating diffusion FD, and charges accumulated in the floating diffusion FD may be reset. In addition, a voltage level in the reset state may be transmitted to the comparator 14 as a pixel signal VPIX (readout in the reset state).

In addition, the control unit 18 may set the PC1 signal to a logic high level and the PC2 signal to a logic low level to turn on SWPC1 and turn off SWPC2 in the selection unit 145. Accordingly, an input of the pixel signal VPIX from the first pixel signal input unit 142 may be valid, and an input of the pixel signal VPIX from the second pixel signal input unit 143 may be invalid.

Before the measurement of the pixel signal VPIX is started, the control unit 18 may set an R1 signal to a logic high level (RampAZ) for a predetermined period to turn on SWR1 to initialize the ramp signal input unit 141. In addition, the control unit 18 may set the P1 signal to a logic high level (PixelAZ) for a predetermined period to turn on SWP1 to initialize the first pixel signal input unit 142.

In operation S102, the control unit 18 may AD-convert the reset level pixel signal VPIX in the LCG mode. The control unit 18 may control the gain select transistor GT to be maintained in the ON state. As illustrated in FIG. 5, the CGS1 signal may be maintained at a logic high level during an “LCG Reset” period for AD-converting the reset level pixel signal VPIX in the LCG mode. As a result, the pixel circuit PX1 may operate in the LCG mode and output the reset level pixel signal VPIX in the LCG mode.

The comparator 14 may receive the pixel signal VPIX from the pixel circuit PX1, compare the reset level pixel signal VPIX in the LCG mode with the ramp signal VRAMP, and output a comparison result. The counter 15 may count a period during which the comparison result from the comparator 14, is at a logic high level. The latch 16 may hold a count value output from the counter 15.

Then, the control unit 18 may set the PC1 signal to a logic low level and the PC2 signal to a logic high level to turn off SWPC1 and turn on SWPC2 in the selection unit 145. As a result, an input of the pixel signal VPIX from the first pixel signal input unit 142 may be invalid, and an input of the pixel signal VPIX from the second pixel signal input unit 143 may be valid.

Moreover, before the ramp signal VRAMP and the pixel signal VPIX are input, the control unit 18 may set the P2 signal to a logic high level (PixelAZ) for a predetermined period to turn on SWP2 to initialize the second pixel signal input unit 143. In addition, SWR1 connected to the ramp signal input unit 141 is already turned on once before Operation S102, so that the transistor TR3 may be initialized in the ramp signal input unit 141. Therefore, SWR1 does not need to be turned on again. For example, as illustrated in FIG. 5, SWR1 is turned on only once immediately after the pixel circuit PX1 is reset to initialize the transistor TR3, and the control unit 18 does not set R1 to a logic high level in the dotted circle part illustrated in FIG. 5.

In operation S103, the control unit 18 may AD-convert the reset level pixel signal VPIX in the HCG mode. The control unit 18 may turn off the gain select transistor GT. As illustrated in FIG. 5, the CGS1 signal may be maintained at a logic low level during the “HCG Reset” period for AD-converting the reset level pixel signal VPIX in the HCG mode. Accordingly, the pixel circuit PX1 may operate in the HCG mode, and the capacitance of the floating diffusion FD may be reduced. As a result, the reset level pixel signal VPIX in the HCG mode may be higher than the reset level pixel signal VPIX in the LCG mode.

The comparator 14 may receive the pixel signal VPIX from the pixel circuit PX1, compare the reset level pixel signal VPIX in the HCG mode with the ramp signal VRAMP, and output a comparison result. The counter 15 may count a period during which the comparison result from the comparator 14 is a logic high level. The latch 16 may hold the count value output from the counter 15.

In operation S104, the control unit 18 may AD-convert the signal level pixel signal VPIX in the HCG mode. The control unit 18 may maintain the gain select transistor GT at an OFF state, and may turn ON the transfer transistor TT. As illustrated in FIG. 5, the CGS1 signal remains at a logic low level during the “HCG Signal” period for AD-converting the signal level pixel signal VPIX in the HCG mode. In addition, the TS signal may be input to the TS input terminal of the transfer transistor TT for a predetermined period.

Light from a subject may be incident on the solid-state imaging device, and charges generated in the photoelectric conversion element PD may be transferred to the floating diffusion FD through the transfer transistor TT and may be then accumulated. Accordingly, a voltage level in the floating diffusion FD may decrease with the amount of transferred charges (electrons). The pixel signal VPIX is transmitted to the comparator 14. For brevity of illustration, FIG. 5 illustrates a case in which a decrease of the voltage level of the floating diffusion FD is small (in the case of DARK).

The comparator 14 may receive the pixel signal VPIX from the pixel circuit PX1, compare the signal level pixel signal VPIX in the HCG mode with the ramp signal VRAMP, and output a comparison result. The counter 15 may count a period during which the comparison result from the comparator 14 is a logic high level. The latch 16 may hold a count value output from the counter 15.

Then, the control unit 18 may set the PC1 signal to a logic high level and the PC2 signal to a logic low level to turn on SWPC1 and turn off SWPC2 in the selection unit 145. Accordingly, an input of the pixel signal VPIX from the first pixel signal input unit 142 may be valid, and an input of the pixel signal VPIX from the second pixel signal input unit 143 may be invalid.

In operation S105, the control unit 18 may AD-convert the signal level pixel signal VPIX in the LCG mode. The control unit 18 may turn on the gain select transistor GT. As illustrated in FIG. 5, the CGS1 signal may be maintained at a logic high level during the “LCG Signal” period for AD-converting the signal level pixel signal VPIX in the LCG mode. The charges generated in the photoelectric conversion element PD may be transferred to the floating diffusion FD through the transfer transistor TT, and may be then accumulated. Accordingly, the voltage level in the floating diffusion FD may decrease with the amount of transferred charges (electrons).

The comparator 14 may receive the pixel signal VPIX from the pixel circuit PX1, compare the signal level pixel signal VPIX in the LCG mode with the ramp signal VRAMP, and output a comparison result. The counter 15 may count the period during which the comparison result from the comparator 14 is a logic high level. The latch 16 may hold the count value output from the counter 15.

As described above, in the present implementation, the pixel circuit PX1 may transmit the pixel signal VPIX to the comparator 14 through the single line CL in a time-serial manner for each conversion gain. The control unit 18 may control the AD conversion unit 20 to AD-convert the reset level pixel signal VPIX in the reset pixel circuit PX1 in the order of LCG mode and HCG mode, and may then AD-convert the signal level pixel signal VPIX corresponding to a captured image in the order of HCG mode and LCG mode.

The comparator 14 may compare the ramp signal VRAMP and the received pixel signal VPIX sequentially for each conversion gain, for example, in a time-serial manner during the AD conversion performed by the AD conversion unit 20.

Next, each latch 16 may perform CDS processing using the AD conversion values of the reset level and the signal level for each mode. For example, the control unit 18 may control each latch 16 to subtract the count value corresponding to the reset level pixel signal VPIX from the count value corresponding to the signal level pixel signal VPIX for the LCG mode and the HCG mode. Accordingly, the latch 16 may calculate the pixel value corresponding to the amount of light received by the photoelectric conversion element PD in each pixel circuit PX1 for the LCG mode and the HCG mode.

The comparator 14 and the solid-state imaging device 10 including the comparator 14 according to the above-described first implementation exhibit the following effects.

In the solid-state imaging device 10, each comparator 14 may include a single ramp signal input unit 141 inputting a ramp signal and a plurality of pixel signal input units 142 and 143, each inputting a pixel signal. Therefore, when the pixel circuit PX1 has a plurality of conversion gains, a plurality of pixel signal input units are provided, but the number of comparator units may be maintained as one. Accordingly, the comparator 14 may suppress an increase in circuit area even when there is a plurality of conversion gains. Therefore, even when the number of conversion gains in the pixel circuit PX1 increases, a decrease in operating speed and an increase in power consumption of the solid-state imaging device 10 may be suppressed.

Based on the configuration of the comparator 14 of the present implementation illustrated in FIG. 3, the area and power consumption of the comparator 14 are calculated using circuit design software. Comparison was also made with comparators having a comparator unit for each conversion gain, such as Comparative Example 1 (Japanese Patent Publication No. 2022-36068) and Comparative Example 2 (US Patent Publication No. 2018/0302578). As a result of the comparison, it was confirmed that the area of the comparator 14 in the present implementation is about 30% smaller than the area of the comparators in Comparative Example 1 and Comparative Example 2. In addition, it was confirmed that the power consumption of the comparator 14 in the present implementation is about half of the power consumption of the comparator in Comparative Example 1. However, the operation speed was the same in the present implementation and the comparative examples.

In the first implementation, a description was provided for a case in which the pixel circuit PX1 is configured to select one of the two conversion gains (the low conversion gain and the high conversion gain), and the comparator 14 includes two pixel signal input units (the first and second pixel signal input units 142 and 143). In the second implementation, a description was provided for a case in which the pixel circuit is configured to select one of the three conversion gains (the high conversion gain, the medium conversion gain, and the low conversion gain), and the comparator includes three pixel signal input units. In addition, the description of components overlapping with those described above in the first implementation will be omitted or simplified to avoid redundancy.

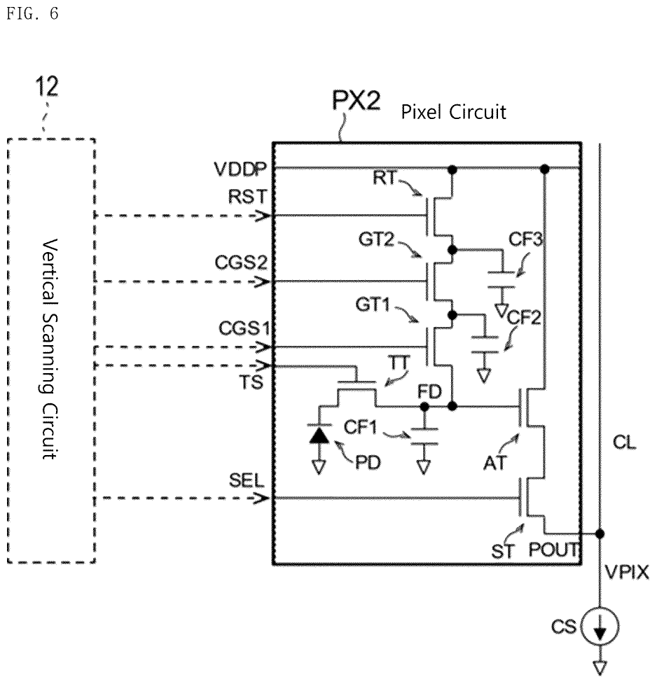

FIG. 6 is a circuit diagram illustrating a pixel circuit of the solid-state imaging device according to the second implementation. Each pixel circuit PX2 may include a photoelectric conversion element PD, a transfer transistor TT, a reset transistor RT, gain select transistors GT1 and GT2, an amplification transistor AT, and a select transistor ST. Each pixel circuit PX2 may perform photoelectric conversion on incident light to output an electrical signal based on the amount of incident light. The solid-state imaging device 10 may select which one of the conversion gain modes to operate in, including a high conversion gain mode in which each pixel circuit PX2 operates at a high conversion gain, a medium conversion gain mode in which each pixel circuit PX2 operates at a medium conversion gain, and a low conversion gain mode in which each pixel circuit PX2 operates at a low conversion gain. In the example illustrated in FIG. 6, the conversion gain mode may be selected by the control signals CGS1 and CGS2. For example, the high conversion gain mode may be selected when CGS1 and CGS2 are at a logic low level, the medium conversion gain mode is selected when CGS1 is at a logic high level and CGS2 is at a logic low level, and the low conversion gain mode is selected when CGS1 and CGS2 are at a logic high level. Hereinafter, the medium conversion gain mode is also referred to as a “middle conversion gain (MCG) mode.”

The gate terminal, the drain terminal, and the source terminal of the reset transistor RT may be connected to the RST input terminal, the pixel power supply VDDP, and the drain terminal of the gain select transistor GT2, respectively. A capacitance CF3 of the floating diffusion may be formed between a connection portion of the source terminal of the reset transistor RT and the drain terminal of the gain select transistor GT2 and the ground.

The gate terminal, the drain terminal, and the source terminal of the gain select transistor GT2 may be connected to a CGS2 input terminal, the source terminal of the reset transistor RT, and the drain terminal of the gain select transistor GT1, respectively.

The gate terminal, the drain terminal, and the source terminal of the gain select transistor GT1 may be connected to the CGS1 input terminal, the source terminal of the gain select transistor GT2, and the drain terminal of the transfer transistor TT, respectively. A capacitance CF2 of the floating diffusion may be formed between a connection portion of the drain terminal of the gain select transistor GT1 and the source terminal of the gain select transistor GT2 and the ground.

The gate terminal, the drain terminal, and the source terminal of the transfer transistor TT may be connected to the TS input terminal, the cathode terminal of the photoelectric conversion element PD, and the source terminal of the gain select transistor GT1, respectively. A capacitance CF1 of the floating diffusion may be formed between a connection portion of the source terminal of the transfer transistor TT and the source terminal of the gain select transistor GT1 and the ground.

The gate terminal, the drain terminal, and the source terminal of the amplification transistor AT may be connected to the source terminal of the transfer transistor TT, the pixel power supply VDDP, and the drain terminal of the select transistor ST, respectively.

The gate terminal, the drain terminal, and the source terminal of the select transistor ST may be connected to the SEL input terminal, the source terminal of the amplification transistor, and the output terminal POUT of the pixel circuit PX2, respectively.

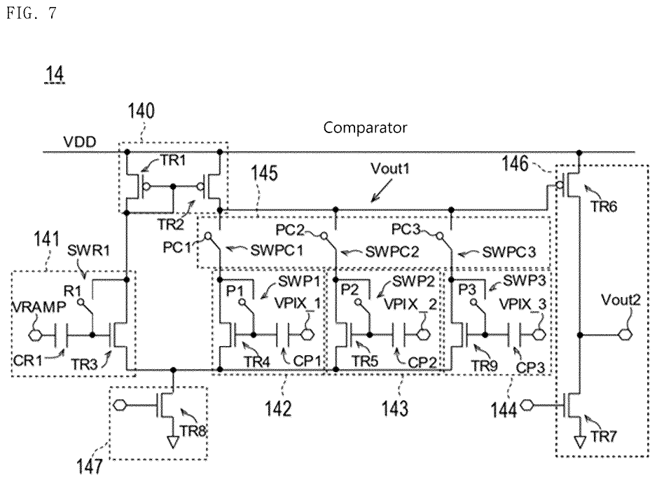

FIG. 7 is a circuit diagram illustrating the configuration of the comparator of the solid-state imaging device according to the second implementation. Each comparator 14 may include a current mirror circuit 140, a ramp signal input unit 141, a first pixel signal input unit 142, a second pixel signal input unit 143, a third pixel signal input unit 144, a selection unit 145, an output circuit 146, and a bias circuit 147.

The configurations of the ramp signal input unit 141, the first pixel signal input unit 142, the second pixel signal input unit 143, the output circuit 146, and the bias circuit 147 are the same as those in the first implementation, and detailed description thereof is omitted.

The third pixel signal input unit 144 may include a VPIX_3 input terminal, an input capacitor CP3, a pixel signal initialization switch SWP3, and a transistor TR9. The input capacitor CP3 may have one terminal connected to the VPIX_3 input terminal, and another terminal connected to the gate terminal of the transistor TR9. The input capacitor CP3 may prevent a DC component, included in the pixel signal VPIX input from the VPIX_3 input terminal, from being transmitted to the transistor TR9.

In the present implementation, the VPIX_1 input terminal of the first pixel signal input unit 142, the VPIX_2 input terminal of the second pixel signal input unit 143, and the VPIX_3 input terminal of the third pixel signal input unit 144 may be connected to each pixel circuit PX2 of the pixel column by a single line CL (see FIGS. 6 and 7).

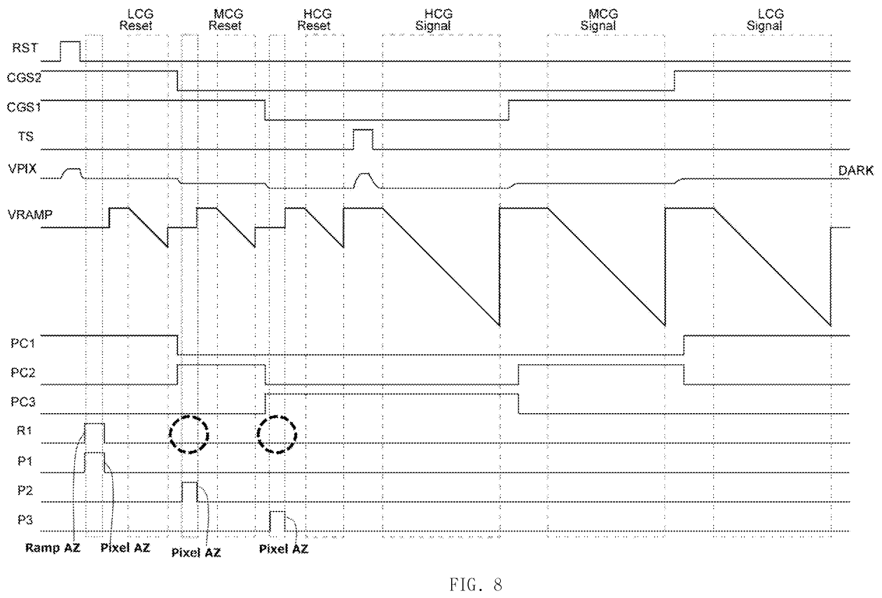

The selection unit 145 may turn on one of the current path control switches SWPC1 to SWPC3 in response to the current path control signals PC1 to PC3. Accordingly, one of the first pixel signal input unit 142, the second pixel signal input unit 143, and the third pixel signal input unit 144 may be selected. The current path control signals PC1 to PC3 may be controlled by the control unit 18 to be mutually exclusively active (see FIG. 8).

The ramp signal input unit 141 and the pixel signal input unit selected by the selection unit 145, among the first pixel signal input unit 142, the second pixel signal input unit 143, and the third pixel signal input unit 144, may form a differential pair unit.

When SWPC1 is turned on, the transistors TR3 (the first transistor) and TR4 (the second transistor) may form a differential pair. The current mirror circuit 140 and the differential pair may function as the comparator unit. When SWPC2 is turned on, the transistors TR3 (the first transistor) and TR5 (the second transistor) may form a differential pair. The current mirror circuit 140 and the differential pair may function as the comparator unit. When SWPC3 is turned ON, the transistors TR3 (the first transistor) and TR9 (the second transistor) may form a differential pair. The current mirror circuit 140 and the differential pair may function as the comparator unit.

FIG. 8 is a timing chart illustrating an overview of the operation of the solid-state imaging device 10 illustrated in FIG. 1. In the present implementation, the control unit 18 may control the AD conversion of the reset level pixel signal VPIX in the order of LCG mode, MCG mode, and HCG mode, and may then control the AD conversion of the signal level pixel signal VPIX in the order of HCG mode, MCG mode, and LCG mode.

The AD conversion of the reset level and signal level pixel signals VPIX in the LCG mode and the HCG mode are the same as those in the first implementation, and detailed description thereof is omitted. Hereinafter, an overview of the AD conversion of the reset level and signal level pixel signals VPIX in the MCG mode is described.

After performing the AD conversion processing on the reset level pixel signal VPIX in the LCG mode, the control unit 18 may set the PC2 signal to a logic high level and the PC1 signal and PC3 signal to a logic low level. Accordingly, SWPC2 may be turned on in the selection unit 145, and SWPC1 and SWPC3 are turned off. As a result, the input of the pixel signal VPIX from the second pixel signal input unit 143 may be valid, and the input of the pixel signal VPIX from the first pixel signal input unit 142 and the third pixel signal input unit 144 may be invalid.

Moreover, before the ramp signal VRAMP and the pixel signal VPIX are input, the control unit 18 may set the P2 signal to a logic high level for a predetermined period to turn on SWP2 to initialize the transistor TR5 in the second pixel signal input unit 143. In addition, SWR1 connected to the ramp signal input unit 141 is already turned on once in the AD conversion processing in the LCG mode and the transistor TR3 is initialized in the ramp signal input unit 141. Therefore, SWR1 does not need to be turned on again. For example, as illustrated in FIG. 8, SWR1 is turned on only once immediately after the pixel circuit PX2 is reset to initialize the transistor TR3, and the control unit 18 does not set R1 to a logic high level in a dashed circular portion illustrated in FIG. 8.

The control unit 18 may AD-convert the reset level pixel signal VPIX in the MCG mode. The control unit 18 may control the gain select transistor GT1 to be maintained in an ON state, and may turn off the gain select transistor GT2. The CGS1 signal may be maintained at a logic high level during the “MCG Reset” period for AD-converting the reset level pixel signal VPIX in the MCG mode. Accordingly, the pixel circuit PX1 may operate in the MCG mode and output the reset level pixel signal VPIX in the MCG mode.

The comparator 14 may receive the pixel signal VPIX from the pixel circuit PX1, compare the reset level pixel signal VPIX in the MCG mode with the ramp signal VRAMP, and output a comparison result. The counter 15 may count the period during which the comparison result from the comparator 14 is at a logic high level. The latch 16 may hold a count value output from the counter 15.

After AD-converting the reset level and signal level pixel signals VPIX in the HCG mode, the control unit 18 AD-converts the signal level pixel signal VPIX in the MCG mode. Before the AD conversion in the MCG mode, the control unit 18 may set the PC2 signal to a logic high level and the PC1 signal and PC3 signal to a logic low level to turn on SWPC2 and turn off SWPC1 and SWPC3 in the selection unit 145. Accordingly, an input of the pixel signal VPIX from the first pixel signal input unit 142 and the third pixel signal input unit 144 may be invalid, and the input of the pixel signal VPIX from the second pixel signal input unit 143 may be valid.

The control unit 18 may turn on the gain select transistor GT1 and maintain the gain select transistor GT2 at an OFF state. The CGS1 signal may be maintained at a logic high level during the “MCG Signal” period for AD-converting the signal level pixel signal VPIX in the MCG mode. Charges generated in the photoelectric conversion element PD may be transferred to the floating diffusion FD through the transfer transistor TT, and may be then accumulated. Accordingly, a voltage level in the floating diffusion FD may decrease with the amount of the transferred charges (electrons).

The comparator 14 may receive the pixel signal VPIX from the pixel circuit PX1, compare the signal level pixel signal VPIX in the MCG mode with the ramp signal VRAMP, and output a comparison result. The counter 15 may count the period during which the comparison result from the comparator 14 is at a logic high level. The latch 16 may hold a count value output from the counter 15.

After the signal level pixel signal VPIX in the HCG mode is AD converted, each latch 16 may perform CDS processing using AD-conversion values of the reset level and the signal level for each mode. For example, the control unit 18 may control each latch 16 to subtract a count value corresponding to the reset level pixel signal VPIX from the count value corresponding to the signal level pixel signal VPIX for the LCG mode, the MCG mode, and the HCG mode. Accordingly, the latch 16 may calculate the pixel value corresponding to the amount of light received by the photoelectric conversion element PD in each pixel circuit PX2 for the LCG mode, the MCG mode, and the HCG mode.

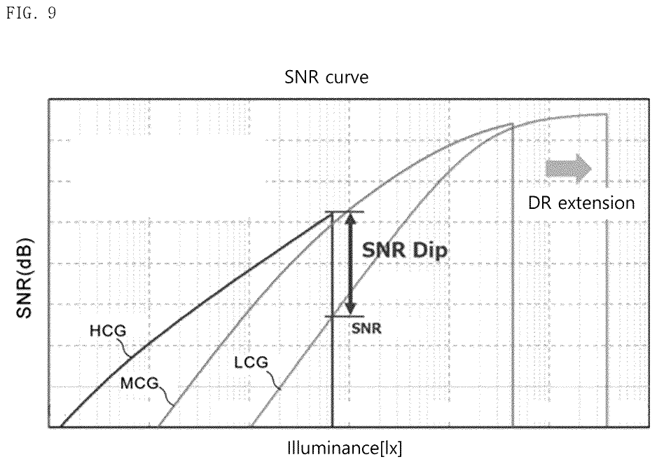

FIG. 9 is a graph illustrating a signal-to-noise ratio (SNR) curve with respect to the illuminance of the solid-state imaging device according to the second implementation. In the drawing, a horizontal axis is illuminance [lx], and a vertical axis is an SNR.

For example, a wide dynamic range (DR) may be achieved using the three conversion gains: high conversion gain, medium conversion gain, and low conversion gain. When attempting to secure the above wide dynamic range using the two conversion gains: high conversion gain and low conversion gain, an SNR dip may occur at medium illuminance. For example, adding a medium conversion gain to the high conversion gain and the low conversion gain may enable the dynamic range to extend toward a high-illuminance side.

Based on the configuration of the comparator 14 of the present implementation illustrated in FIG. 7, an area and power consumption of the comparator 14 were calculated using circuit design software. Comparison was also made with comparators having a comparator unit for each conversion gain, such as Comparative Example 1 (Patent Publication No. 2022-36068) and Comparative Example 2 (US Patent Publication No. 2018/0302578). As a result of the comparison, it was confirmed that the area and power consumption of the comparator 14 in the present implementation are further reduced than the area and power consumption of the comparator 14 in the first implementation. However, the operation speed was the same in the present implementation and the comparative examples.

In the first implementation, a description was provided for a case in which the pixel circuit PX1 has a single photoelectric conversion element PD. In the third implementation, a description was provided for a case in which the pixel circuit has two photoelectric conversion elements. Furthermore, the description of components overlapping with those described above in the first implementation is omitted and simplified to avoid redundancy.

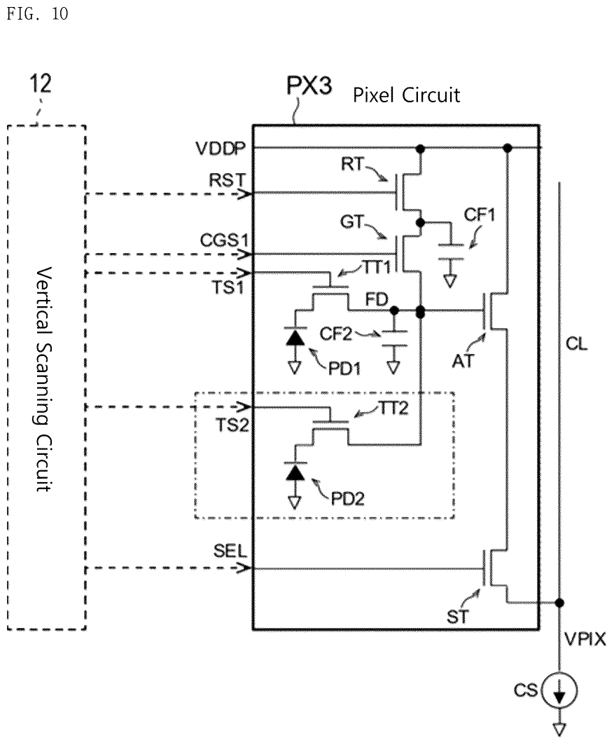

FIG. 10 is a circuit diagram illustrating a pixel circuit of a solid-state imaging device according to the third implementation. A pixel circuit PX3 may include photoelectric conversion elements PD1 and PD2, transfer transistors TT1, TT2, a reset transistor RT, a gain select transistor GT, an amplification transistor AT, and a select transistor ST. The photoelectric conversion element PD1, the transfer transistor TT1, the reset transistor RT, the gain select transistor GT, the amplification transistor AT, and the select transistor ST of the pixel circuit PX3 in the present implementation correspond to the photoelectric conversion element PD, the transfer transistor TT, the reset transistor RT, the gain select transistor GT, the amplification transistor AT, and the select transistor ST of the pixel circuit PX1 in the first implementation, respectively.

For example, the pixel circuit PX3 in the present implementation may further include the photoelectric conversion element PD2 and the transfer transistor TT2 in addition to the configuration of the pixel circuit PX1 in the first implementation (a portion enclosed by the dashed-dotted line in FIG. 10). A gate terminal, a drain terminal, and a source terminal of the transfer transistor TT2 may be connected to a TS2 input terminal, a cathode terminal of the photoelectric conversion element PD2, and the source terminal of the gain select transistor GT, respectively.

The photoelectric conversion element PD2 may be a photodiode or a phototransistor, or the like, having a sensitivity different from that of the photoelectric conversion element PD1. For example, the photoelectric conversion element PD2 may be a photoelectric conversion element having a lower sensitivity than the photoelectric conversion element PD1. The pixel circuit PX3 may be controlled by the control unit 18 to convert the charge, generated by the photoelectric conversion element PD2 and transferred to the floating diffusion FD, into a voltage at a low conversion gain. Accordingly, the dynamic range may extend toward the high illuminance side. For example, even a scene having a higher illuminance (brighter) may be reproduced as an image.

In addition, the pixel circuit PX3 may be controlled by the control unit 18 to convert the charge, generated by the photoelectric conversion element PD1 having a higher sensitivity than the photoelectric conversion element PD2 and transferred to the floating diffusion FD, into a voltage at a high conversion gain. Accordingly, the dynamic range may extend toward a low-illuminance side. For example, even a scene having a lower illuminance (darker) may be reproduced as an image.

The configuration of the comparator of the solid-state imaging device 10 in the present implementation is the same as the configuration of the comparator 14 of the solid-state imaging device 10 in the first implementation, and detailed description thereof is omitted.

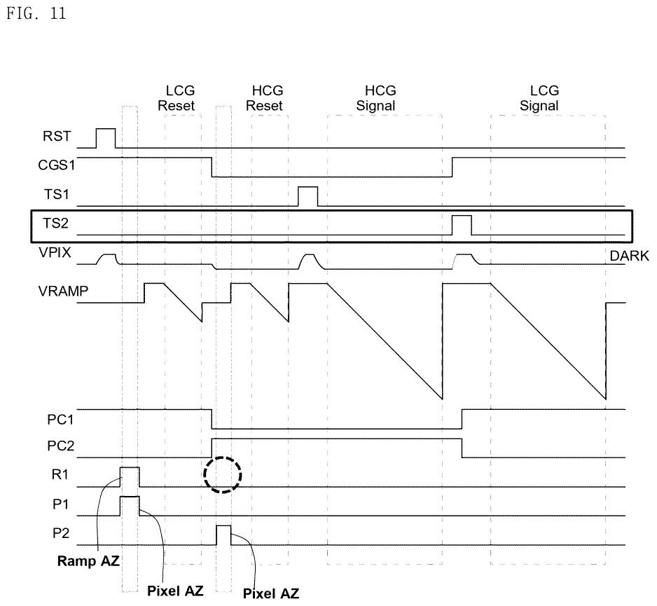

FIG. 11 is a timing chart illustrating an overview of an operation of the solid-state imaging device 10 according to the third implementation.

The processing up to the AD conversion of the reset level pixel signal VPIX in the LCG mode and the HCG mode and the AD conversion of the signal level pixel signal VPIX in the HCG mode is the same as the processing in the timing chart illustrated in FIG. 5 in the first implementation. In the HCG mode, the transfer transistor TT1 may be turned on by a TS1 control signal. Accordingly, the charge generated in the photoelectric conversion element PD1 may be transferred to the floating diffusion FD through the transfer transistor TT1, and may be then accumulated. In the HCG mode, the charge generated in the photoelectric conversion element PD1 may be converted into a voltage and output as the pixel signal VPIX.

Before the AD conversion of the signal level pixel signal VPIX in the LCG mode, the transfer transistor TT2 may be turned on by a TS2 control signal. Accordingly, the charge generated in the photoelectric conversion element PD2 may be transferred to the floating diffusion FD through the transfer transistor TT2, and may be then accumulated. In the LCG mode, the charge generated in the photoelectric conversion element PD2 may be converted into a voltage and output as the pixel signal VPIX.

As described above, in the present implementation, the pixel circuit PX3 may transmit the pixel signal VPIX to the comparator 14 through the single line CL in a time-serial manner for the photoelectric conversion elements PD1 and PD2 (a plurality of pixels). The control unit 18 may control the AD conversion unit 20 to AD-convert the reset level pixel signal VPIX in the reset pixel circuit PX1 in the order of LCG mode and HCG mode, and may then AD-convert the signal level pixel signal VPIX corresponding to a captured image in the order of HCG mode and LCG mode. The comparator 14 may compare the pixel signal VPIX from the photoelectric conversion elements PD1 and PD2 (a plurality of pixels) with the ramp signal VRAMP sequentially for each pixel during the AD conversion performed by the AD conversion unit 20.

After the signal level pixel signal VPIX in the LCG mode is AD-converted, each latch 16 may perform CDS processing using the AD conversion values of the reset level and the signal level for each mode.

The control unit 18 may control each latch 16 to subtract a count value corresponding to the reset level pixel signal VPIX from a count value corresponding to the signal level pixel signal VPIX for the LCG mode and the HCG mode. Accordingly, the latch 16 may calculate a pixel value corresponding to the amount of light received by the photoelectric conversion element PD1 in each pixel circuit PX3 for the HCG mode, and may calculate a pixel value corresponding to the amount of light received by the photoelectric conversion element PD2 in each pixel circuit PX3 for the LCG mode.

As described above, according to the third implementation, the following effects are exhibited in addition to the effects of the first implementation.

The pixel circuit PX3 may include two photoelectric conversion elements PD1 and PD2 (a plurality of pixels) having different sensitivities, common to the floating diffusion FD. The pixel circuit is configured such that the charge generated by the low-sensitivity photoelectric conversion element among the photoelectric conversion elements PD1 and PD2 and transferred to the floating diffusion FD is converted into a voltage at a low conversion gain to extend the dynamic range toward a high-illuminance side. In addition, the charge generated by the high-sensitivity photoelectric conversion element among the photoelectric conversion elements PD1 and PD2 and transferred to the floating diffusion FD is converted into a voltage at a high conversion gain to extend the dynamic range toward a low-illuminance side.

A fourth implementation describes a case where the pixel circuit is configured to select one of three conversion gains, similar to the second implementation, and the comparator has three pixel signal input units, and where the pixel circuit is configured to have two photoelectric conversion elements, similar to the third implementation. In addition, descriptions of the components overlapping with those in the first through third implementations will be omitted or simplified to avoid redundancy.

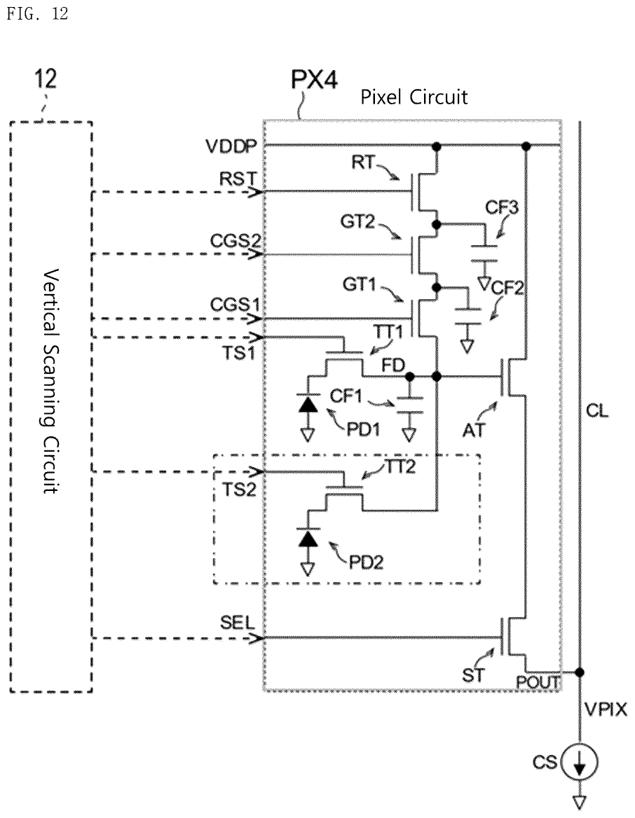

FIG. 12 is a circuit diagram illustrating a pixel circuit of a solid-state imaging device according to the fourth implementation. A pixel circuit PX4 may include photoelectric conversion elements PD1 and PD2, transfer transistors TT1 and TT2, a reset transistor RT, gain select transistors GT1 and GT2, an amplification transistor AT, and a select transistor ST. The photoelectric conversion element PD1, the transfer transistor TT1, the reset transistor RT, the gain select transistor GT1, the amplification transistor AT, and the select transistor ST of the pixel circuit PX4 in the present implementation correspond to the photoelectric conversion element PD, the transfer transistor TT, the reset transistor RT, the gain select transistor GT, the amplification transistor AT, and the select transistor ST of the pixel circuit PX2 in the second implementation, respectively.

In the present implementation, the pixel circuit PX4 may further include the photoelectric conversion element PD2 and the transfer transistor TT2 of the third implementation in addition to the configuration of the pixel circuit PX2 in the second implementation (a portion enclosed by the dashed-dotted line in FIG. 12). A gate terminal, a drain terminal, and a source terminal of the transfer transistor TT2 may be connected to a TS2 input terminal, a cathode terminal of the photoelectric conversion element PD2, and a source terminal of the gain select transistor GT1, respectively.

The configuration of the comparator of the solid-state imaging device 10 in the present implementation is the same as the configuration of the comparator 14 of the solid-state imaging device 10 in the second implementation, and detailed description thereof is omitted.

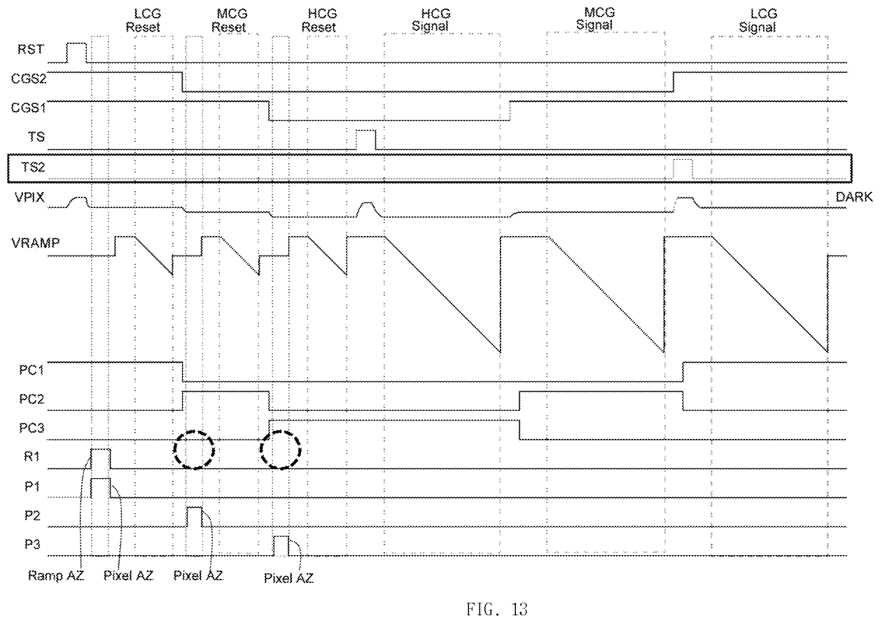

FIG. 13 is a timing chart illustrating an overview of the operation of the solid-state imaging device 10 according to the fourth implementation.

The processing up to the AD conversion of the reset level pixel signal VPIX in each of the LCG, MCG, and HCG modes, or the AD conversion of the signal level pixel signal VPIX in each of the HCG and MCG modes is the same as the processing in the timing chart illustrated in FIG. 8 of the second implementation. In addition, the processing of the AD conversion of the signal level pixel signal VPIX in the LCG mode is the same as the processing in the timing chart illustrated in FIG. 11 of the third implementation.

In the fourth implementation, the effects of the third implementation may be exhibited in addition to the effects of the second implementation. For example, the pixel circuit PX4 may be configured to select one of the three conversion gains (high conversion gain, medium conversion gain, and low conversion gain), and the comparator 14 may have three pixel signal input units. Adding the medium conversion gain to the high conversion gain and the low conversion gain may enable the dynamic range to extend toward a high-illuminance side. Furthermore, the pixel circuit PX4 may have two photoelectric conversion elements PD1 and PD2 (a plurality of pixels) having different sensitivities, common to a floating diffusion FD. A charge generated by the photoelectric conversion element having the lower sensitivity, among the photoelectric conversion elements PD1 and PD2, may be converted into a voltage at a low conversion gain, and the charge generated by the photoelectric conversion element having the higher sensitivity may be converted into a voltage at a high conversion gain. As a result, a dynamic range may extend toward both the low-illuminance side and the high-illuminance side.

As described above, the comparator and the solid-state imaging device according to implementations of the present disclosure have been described. However, it will be understood that those skilled in the art may appropriately add, modify, and omit them within the present disclosure.

For example, in the second and fourth implementations described above, a description has been provided for a case in which the comparator 14 has three pixel signal input units, but the number of pixel signal input units that the comparator 14 has may be four or more.

Furthermore, in the third and fourth implementations described above, a description has been provided for a case in which the pixel circuits PX3 and PX4 have two photoelectric conversion elements PD1 and PD2 having different sensitivities, common to a floating diffusion FD. However, the number of photoelectric conversion elements that the pixel circuit has is not limited to two, and may be three or more.

Furthermore, in the first to fourth implementations described above, a solid-state imaging device including a plurality of pixel circuits including a photoelectric conversion element such as a photodiode in a pixel has been described. However, the present disclosure is not limited to such a case and may be applied to an AD conversion unit that AD-converts an analog signal from an optical sensor using an optical sensor instead of the pixel circuit. Such an optical sensor includes, for example, an illuminance sensor, a contrast sensor, or an infrared distance sensor.

Furthermore, the solid-state imaging device of the present disclosure may be used in various devices sensing light such as visible light, near-infrared light, infrared light, ultraviolet light, or X-rays. Such devices include, but are not limited to, for example, a smartphone, a mobile phone, a personal computer, office equipment, vehicle-mounted equipment, medical equipment, entertainment equipment, natural observation equipment, and security equipment. For example, the solid-state imaging device of the present disclosure may be used in a visible light camera, such as a smartphone, a mobile phone, or a digital camera. Furthermore, the solid-state imaging device of the present disclosure may also be used in time-of-flight (TOF) or light detection and ranging (LiDAR) along with a light emitting device.

As set forth above, in the solid-state imaging device according to the present disclosure, each comparator may be configured to include a single ramp signal input unit inputting a ramp signal and a plurality of pixel signal input units, each inputting a pixel signal. Accordingly, when the number of conversion gains in the pixel configuration is a plurality, the number of pixel signal input units is a plurality, but the number of comparator units may be maintained as one. Accordingly, the comparator of the present disclosure may reduce an increase in circuit area even when the number of conversion gains is a plurality. Accordingly, even when the number of conversion gains in the pixel configuration is large, the comparator may suppress a decrease in operating speed and an increase in power consumption of the solid-state imaging device.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A comparator of an AD conversion circuit, wherein the AD conversion circuit is configured to convert an analog pixel signal into a digital signal, the comparator comprising:
a ramp signal input circuit configured to receive a ramp signal and output a ramp-side signal;
a plurality of pixel signal input circuits, each configured to receive the analog pixel signal and output a pixel-side signal; and
a comparison circuit configured to:
compare the ramp-side signal received from the ramp signal input circuit, with the pixel-side signal received from one of the plurality of pixel signal input circuits, and
output a comparison result.

2. The comparator of claim 1, comprising a selection circuit configured to select the one of the plurality of pixel signal input circuits.

3. The comparator of claim 2, wherein the ramp signal input circuit and the selected one of the pixel signal input circuits define a differential pair circuit,
wherein the differential pair circuit comprises:
a first transistor in the ramp signal input circuit and configured to receive the ramp signal,
a first switch in the ramp signal input circuit and configured to initialize the first transistor,
a second transistor in the selected one of the pixel signal input circuits and configured to receive the analog pixel signal, and
a second switch in the selected one of the pixel signal input circuits and configured to initialize the second transistor,
wherein the first switch is configured to be turned on to initialize the first transistor, and
wherein the second switch is configured to be turned on to initialize the second transistor.

4. The comparator of claim 3,
wherein the first switch is configured to connect a gate terminal with a source terminal or a drain terminal of the first transistor,
wherein the second switch is configured to connect a gate terminal with a source terminal or a drain terminal of the second transistor,
wherein the first switch is configured to be turned on to connect the gate terminal with the source terminal or the drain terminal of the first transistor to initialize the first transistor, and
wherein the second switch is configured to be turned on to connect the gate terminal with the source terminal or the drain terminal of the second transistor to initialize the second transistor.

5. A solid-state imaging device comprising:
a pixel configuration configured to switch a conversion gain corresponding to a rate at which a charge generated in a pixel is converted into a voltage; and
an AD conversion circuit configured to receive an analog pixel signal from the pixel configuration and convert the analog pixel signal into a digital signal, the AD conversion circuit comprising a comparator,
wherein the comparator comprises:
a ramp signal input circuit configured to receive a ramp signal and output a ramp-side signal;
a plurality of pixel signal input circuits, each configured to receive the analog pixel signal and output a pixel-side signal;
a selection circuit configured to select one of the plurality of pixel signal input circuits based on the conversion gain; and
a comparison circuit configured to:
compare the ramp-side signal received from the ramp signal input circuit with the pixel-side signal received from the selected one of the plurality of pixel signal input circuits, and
output a comparison result.

6. The solid-state imaging device of claim 5, wherein the comparison circuit is configured to sequentially compare the ramp-side signal with the pixel-side signal based on a conversion gain mode.

7. The solid-state imaging device of claim 6,
wherein the analog pixel signal from the pixel configuration comprises a reset level pixel signal at a first time, the reset level pixel signal being output based on the pixel configuration being reset,
wherein the analog pixel signal from the pixel configuration comprises a signal level pixel signal at a second time after the first time, the signal level pixel signal corresponding to a captured image,
wherein the comparison circuit is configured to, based on the conversion gain mode:
compare the pixel-side signal generated based on the reset level pixel signal with the ramp-side signal at a third time, and
compare the pixel-side signal generated based on the signal level pixel signal with the ramp-side signal at a fourth time after the third time.

8. The solid-state imaging device of claim 5,
wherein the ramp signal input circuit and the selected one of the pixel signal input circuit serve as a differential pair circuit,
wherein the differential pair circuit comprises:
a first transistor in the ramp signal input circuit and configured to receive the ramp signal,
a first switch in the ramp signal input circuit and configured to initialize the first transistor,
a second transistor in the selected one of the pixel signal input circuits and configured to receive the analog pixel signal, and
a second switch in the selected one of the pixel signal input circuits and configured to initialize the second transistor,
wherein the first switch is configured to be turned on, based on the pixel configuration being reset, to initialize the first transistor, and
wherein the second switch is configured to be turned on, based on a conversion gain mode, to initialize the second transistor.

9. The solid-state imaging device of claim 8,
wherein the first switch is configured to connect a gate terminal with a source terminal or a drain terminal of the first transistor,
wherein the second switch is configured to connect a gate terminal with a source terminal or a drain terminal of the second transistor,
wherein the first switch is configured to be turned on, based on the pixel configuration being reset, to connect the gate terminal with the source terminal or the drain terminal of the first transistor to initialize the first transistor, and
wherein the second switch is configured to be turned on, based on the conversion gain, to connect the gate terminal with the source terminal or the drain terminal of the second transistor to initialize the second transistor.

10. The solid-state imaging device of claim 5, wherein the pixel configuration comprises a plurality of pixels having different sensitivities.

11. The solid-state imaging device of claim 10, wherein the comparison circuit is configured to sequentially compare the pixel-side signals from the plurality of pixels with the ramp-side signal for each pixel.

12. The solid-state imaging device of claim 11,
wherein the analog pixel signal from the pixel configuration comprises a reset level pixel signal at a first time, the reset level pixel signal being output based on the pixel configuration being reset,
wherein the analog pixel signal from the pixel configuration comprises a signal level pixel signal at a second time after the first time, the signal level pixel signal corresponding to a captured image,
wherein the comparison circuit is configured to, based on a conversion gain mode:
compare the reset level pixel signal with the ramp-side signal at a third time, and
compare the signal level pixel signal with the ramp-side signal at a fourth time after the third time.

13. The solid-state imaging device of claim 10,
wherein the ramp signal input circuit and the selected one of the pixel signal input circuits serve as a differential pair circuit,
wherein the differential pair circuit comprises:
a first transistor in the ramp signal input circuit and configured to receive the ramp signal,
a first switch in the ramp signal input circuit and configured to initialize the first transistor,
a second transistor in the selected one of the pixel signal input circuits and configured to receive the analog pixel signal, and
a second switch in the selected one of the pixel signal input circuits and configured to initialize the second transistor,
wherein the first switch is configured to be turned on, based on the pixel configuration being reset, to initialize the first transistor, and
wherein the second switch is configured to be turned on, based on a conversion gain mode to initialize the second transistor.

14. The solid-state imaging device of claim 13,
wherein the first switch is configured to connect a gate terminal with a source terminal or a drain terminal of the first transistor,
wherein the second switch is configured to connect a gate terminal with a source terminal or a drain terminal of the second transistor.
wherein the first switch is configured to be turned on, based on the pixel configuration being reset, to connect the gate terminal with the source terminal or the drain terminal of the first transistor to initialize the first transistor, and
wherein the second switch is configured to be turned on, based on a conversion gain mode to connect the gate terminal with the source terminal or the drain terminal of the second transistor to initialize the second transistor.

15. The solid-state imaging device of claim 10,
wherein the comparator comprises a differential pair circuit configured to differentially amplify the ramp-side signal and the pixel-side signal,
wherein the differential pair circuit comprises:
a first switch in the ramp signal input circuit and configured to initialize a first transistor configured to receive the ramp signal, and
a second switch in the selected one of the pixel signal input circuits and configured to initialize a second transistor configured to receive the analog pixel signal,
wherein the first switch is configured to be turned on, based on the pixel configuration being reset, to initialize the first transistor, and
wherein the second switch is configured to be turned on, based on the conversion gain, to initialize the second transistor.

16. The solid-state imaging device of claim 5, wherein the pixel configuration and the plurality of pixel signal input circuits are connected by a single line.

17. The solid-state imaging device of claim 5,
wherein the comparator comprises a differential pair circuit configured to differentially amplify the ramp-side signal and the pixel-side signal,
wherein the differential pair circuit comprises:
a first switch configured to initialize a first transistor configured to receive the ramp signal, and
a second switch configured to initialize a second transistor configured to receive the analog pixel signal,
wherein the first switch is configured to be turned on, based on the pixel configuration being reset, to initialize the first transistor, and
wherein the second switch is configured to be turned on, based on a conversion gain mode, to initialize the second transistor.

18. A solid-state imaging device comprising:
a pixel configuration configured to switch a conversion gain corresponding to a rate at which a charge generated in a pixel is converted into a voltage; and
a comparator comprising:
a ramp signal input circuit configured to receive a ramp signal and output a ramp-side signal;
a plurality of pixel signal input circuits, each configured to receive an analog pixel signal from the pixel configuration and output a pixel-side signal; and
a comparison circuit configured to:
compare the ramp-side signal received from the ramp signal input circuit with the pixel-side signal received from a first pixel signal input circuit of the plurality of pixel signal input circuits, and
output a comparison result.

19. The solid-state imaging device of claim 18,
wherein the ramp signal input circuit comprises:
a first transistor configured to receive the ramp signal,
a first switch configured to initialize the first transistor,
wherein the first pixel signal input circuit of the pixel signal input circuits comprises:
a second transistor configured to receive the analog pixel signal, and
a second switch configured to initialize the second transistor,
wherein the first switch is configured to be turned on, based on the pixel configuration being reset, to initialize the first transistor, and
wherein the second switch is configured to be turned on, based on the conversion gain, to initialize the second transistor.

20. The solid-state imaging device of claim 19,
wherein the first switch is configured to connect a gate terminal with a source terminal or a drain terminal of the first transistor,
wherein the second switch is configured to connect a gate terminal with a source terminal or a drain terminal of the second transistor.
wherein the first switch is configured to be turned on, based on the pixel configuration being reset, to connect the gate terminal with the source terminal or the drain terminal of the first transistor to initialize the first transistor, and
wherein the second switch is configured to be turned on, based on the conversion gain, to connect the gate terminal with the source terminal or the drain terminal of the second transistor to initialize the second transistor.
